(19) United States
(12) Patent Application Publication
(10) Pub. No.: US 2025/0370900 A1
(43) Pub. Date: Dec. 4, 2025

(54) METHODS AND SYSTEMS FOR MULTI-CHANNEL, MULTI-TENANT BATTERY CYCLING

(71) Applicant: Iontra Inc, Centennial, CO (US)

(72) Inventors: Zhong WANG, Sugar Land, TX (US); Daniel A. KONOPKA, Aurora, CO (US); John Richard HOWLETT, III, Centennial, CO (US); Hunter KRIEG, Allen, TX (US); Manoj K. KOUL, Allen, TX (US); Chaise Conn, Puyallup, WA (US); Lang Xia, Boyds, MD (US)

(21) Appl. No.: 19/225,863

(22) Filed: Jun. 2, 2025

Related U.S. Application Data
(60) Provisional application No. 63/654,670, filed on May 31, 2024.
(60) Provisional application No. 63/654,646, filed on May 31, 2024.

(51) Int. Cl. G06F 11/34; G06F 1/28

(52) U.S. Cl. CPC G06F 11/3457; G06F 1/28

(57) ABSTRACT

Aspects of the present disclosure relate to a method of developing a battery charging profile. The method includes performing an experimentation process on a battery, performing a parameterization process on the battery, developing a battery model for the battery based on experimentation data and parameterization data, generating simulated battery data using the battery model, and generating a battery performance report based on the simulated battery data. Other aspects relate to a multi-channel, multi-tenant system for developing a battery charging profile. The system includes a first battery cycler and a second battery cycler, wherein the first and second battery cyclers are configured to deliver a charge signal to a battery disposed therein. The system also includes a data storage infrastructure in communication with the first and second cyclers and a multi-tenant data processing application stored on the data storage infrastructure.

### CROSS-REFERENCE TO RELATED APPLICATIONS

This application claims priority to U.S. Provisional Patent Application 63/654,670, filed May 31, 2024, and entitled “METHODS AND SYSTEMS FOR MULTI-CHANNEL, MULTI-TENANT BATTERY CYCLING,” which is incorporated herein by reference. This application also claims priority to U.S. Provisional Patent Application 63/654,646, filed May 31, 2024, and entitled “METHODS AND SYSTEMS FOR MULTI-CHANNEL, MULTI-TENANT BATTERY CYCLING”, which is incorporated herein by reference.

### TECHNICAL FIELD

Embodiments of the present invention generally relate to systems and methods for developing a battery charging profile optimized to a battery and its usage requirements.

### BACKGROUND and INTRODUCTION

Battery powered devices have proliferated and become ubiquitous. Device manufacturers are constantly pressing for performance improvement in batteries, particularly as batteries are introduced into devices with relatively higher current demands and power needs. At the same time, consumers demand longer battery life, longer times between charges, and shorter charge times. As such, there is an ongoing and continuous need for improvements in how batteries are managed, charged, and discharged to enhance performance of the battery and the system using the battery. Among other things, cost-effective and accessible systems and methods for developing optimized battery charging profiles, discharging profiles and other uses recipes are needed to meet these demands.

It is with these observations in mind, among others, that aspects of the present disclosure were conceived.

### SUMMARY

One aspect of the present disclosure relates to a method of developing a battery charging profile. The method may include performing an experimentation process on a battery, performing a parameterization process on the battery, developing a battery model for the battery based on experimentation data and parameterization data, generating simulated battery data using the battery model, and generating a battery performance report based on the simulated battery data.

Another aspect of the present disclosure relates to a multi-channel, multi-tenant system for developing a battery charging profile. The system includes a first battery cycler and a second battery cycler, wherein the first and second battery cyclers are configured to deliver a charge signal to a battery disposed therein. The system also includes a data storage infrastructure in communication with the first and second cyclers and a multi-tenant data processing application stored on the data storage infrastructure. The multi-tenant data processing application is configured to receive first cycling data from the first battery cycler and second cycling data from the second battery cycler. The multi-tenant data processing application is configured to route the first cycling data to a first data store on the data storage infrastructure and is configured to route the second cycling data to a second data store on the data storage infrastructure.

### BRIEF DESCRIPTION OF THE DRAWINGS

The various objects, features, and advantages of the present disclosure set forth herein will be apparent from the following description of embodiments of those inventive concepts, as illustrated in the accompanying drawings. Drawings presented herein are not necessarily to scale and may be representative of various features of an embodiment, with emphasis being placed on illustrating the principles and other aspects of the inventive concepts. Also, in the drawings the like reference characters may refer to the same parts or similar throughout the different views. It is intended that the embodiments and figures disclosed herein are considered illustrative rather than limiting.

FIG. 1 is a block diagram of a battery charge recipe development workflow, in accordance with embodiments herein.

FIG. 2 is a block diagram of a battery parameterization workflow, in accordance with embodiments herein.

FIG. 3 is a table showing example parameters that may be obtained through a parameterization workflow, in accordance with embodiments herein.

FIG. 4 lists equations that may be used to calculate battery parameters such as intercalation/deintercalation, solid-electrolyte interface, lithium plating/stripping, mass conservation, charge conservation, interface condition, and thermal response, in accordance with embodiments herein.

FIGS. 5A-5C show graphs of simulated voltage, temperature, and capacity loss data compared to actual measured voltage, temperature and capacity loss data for simulation validation, in accordance with embodiments herein.

FIG. 6A shows an example performance report for a battery that may be provided to a user, in accordance with embodiments herein.

FIG. 6B shows an example selection of interest based on a performance report for a battery, in accordance with embodiments herein.

FIG. 6C shows a refined performance report for a selection of interest, in accordance with embodiments herein.

FIG. 7 shows a block diagram of a system that may be used for training and/or optimizing a Model Predictive Controller (MPC), in accordance with embodiments herein.

FIGS. 8A-8D show example metrics (Temperature, Current, State of Charge (SOC), and Overpotential, respectively) as a function of time for a battery under the control of a trained MPC with pre-determined threshold limits, in accordance with embodiments herein.

FIG. 9 shows a block diagram for a process that may be used to pre-qualify one or more batteries, in accordance with embodiments herein.

FIG. 10 shows a hardware- and software-based system for performing battery cycling and organizing resulting data into a secure dashboard, in accordance with embodiments herein.

FIG. 11 shows an example of a circuit that may be used to generate a charging and/or heating signal of any desired shape, in accordance with embodiments herein.

FIG. 12 shows an example system for triggering, controlling, and/or receiving measurements from hardware devices such as a cell thickness measurement apparatus, a temperature-controlled chamber, or an EIS/ICA measurement apparatus, in accordance with embodiments herein.

FIG. 13 is a diagram illustrating an example of a computing system which may be used in implementing embodiments, or portions of embodiments, of the present disclosure.

### DETAILED DESCRIPTION

Battery longevity and charging speed can be greatly improved through the use of charging recipe, discharging recipe, and/or cold weather mitigation (e.g., heating) recipes that provide specific charge current profiles, discharge current profiles, and/or cold weather mitigation currents to and/or from the battery that are optimized for the specific battery and its application, which may be static or adjusted based on battery age, number of charge cycles, starting state of charge, and any number of other attributes. A recipe defines some form of current to or from the battery that is not a simple steady state DC current, although certainly some periods of current may be at a steady DC current. Using the example of a charge recipe, an optimized recipe developed according to the techniques described herein will enhance one or more areas associated with a battery charge including extending battery life, hitting “fast charging” objectives—e.g., charge to 80% within 10 minutes, charging within temperature ranges or avoiding over temperature conditions, etc. The application primarily discusses and provides examples of the development of charge recipes, and the concepts described may be extended to discharge (providing power to a load) and/or temperature management.

Developing optimized recipes for a battery is challenging and often requires significant time and resources. In some cases, developing a charging recipe involves performing a series of experiments on a battery so that different combinations of variables and their effect on the battery can be evaluated. Each test may take several days to fully complete and may need to be performed multiple times to ensure that reliable results are obtained. Testing may also require expensive hardware, sufficient space to house the hardware, several new batteries per test, safety equipment and monitoring, and personnel with the technical expertise to operate the hardware and interpret findings. At the end of the testing process, a user may select the battery charging recipe that performs best out of the tested conditions. However, because not every combination of variables can be tested due to resource limitations, the selected recipe may not be fully optimized to the battery's capabilities. Additionally, even after testing, the user may not have solid understanding of the full range of performance tradeoffs associated with different variable selections for the charging recipe. In general, an optimize recipe provides several advantages whereas charging a battery without a recipe or a non-optimized recipe, may may result in any number of performance issues including plating, dendrite formation, slow charging speeds, reduced battery cycle life, or other detrimental battery performance. These issues may lead to a poor user experience and may even require more frequent battery replacement, thereby negatively impacting the environment. Thus, methods and systems for facilitating access to better charge recipe development are desired.

Systems and methods herein advantageously support the development of a fully optimized charging recipe while requiring fewer experimental tests, requiring fewer new battery cells, including automated processes to reduce development time and technician involvement, and providing for secure, remote access of battery data and charging recipe data by users. A thorough understanding of the battery may be developed by using methods herein. Specifically, the data and reports generated may provide detailed information about the battery, its capabilities and design tradeoffs, and its suitability for different applications. Moreover, the charging recipe (or other recipes) may be integrated into a battery management system or other battery charge control systems to manage charge, discharge, or other issues related to a battery.

Additionally, the systems and methods described may allow for equipment (e.g., battery cyclers) to be stored remotely and accessed by a user to develop a charging recipe without purchasing, storing, maintaining, and operating the equipment. Additionally, the systems and methods described herein improve charging recipe optimization for a battery and provide a user with an improved understanding of the battery's capabilities while making the charge recipe development process significantly less resource intensive. Thus, concepts disclosed herein make charge recipe development and optimization more accessible and practical for a variety of products and applications.

Various battery measurements may be performed in situ (e.g., without removing the battery from a cycler apparatus) while other battery measurements may be performed as part of a characterization phase that occurs while the battery is disconnected from the cycler. In some embodiments, the cycling apparatus includes hardware to support electrochemical impedance spectroscopy (EIS), incremental capacity analysis (ICA), physical dimension measurements (e.g., cell thickness), and/or contact impedance measurements. The apparatus may also measure voltage at the battery under test (BUT) and current to or from the BUT, as well temperature while the battery is being cycled. These and other measurements and testing processes may be used to develop a highly optimized battery cell- or pack-specific charging protocol.

In some embodiments, the disclosed battery cycler software enables remote control of the cycler apparatus through a web-based or cloud-based user interface. For example, one or more stages of a charging protocol development workflow may be performed, initiated, adjusted, paused, stopped, scheduled, rescheduled, and/or rerun on remotely located equipment controlled through the user interface. Specifically, remote control of the cycler may be enabled by signals (e.g., electrical communication) controlled through a software-controlled master. This innovative approach allows for new ways of interacting with a cycler apparatus and improved methods of developing a highly optimized charging protocol in less time.

The following disclosure relates to an apparatus, methods, and system for automated and calibrated measurement of electrical and/or physical battery cell and/or pack properties. The use of the term “battery” may refer to a battery cell or a battery pack. The term “battery” in the art and herein can be used in various ways and may refer to an individual cell having an anode and cathode separated by an electrolyte, solid or liquid, as well as a collection of such cells connected in various arrangements. A battery or battery cell is a form of electrochemical device. Batteries generally comprise repeating units of sources of a countercharge and electrode layers separated by an ionically conductive barrier, often a liquid or polymer membrane saturated with an electrolyte. These layers are made to be thin so multiple units can occupy the volume of a battery, increasing the available power of the battery with each stacked unit. Although many examples are discussed herein as applicable to a battery, it should be appreciated that the systems and methods described may apply to many different types of batteries ranging from an individual cell to batteries involving different possible interconnections of cells, such as cells coupled in parallel, series, and parallel and series. For example, the systems and methods discussed herein may apply to a battery pack comprising numerous cells arranged to provide a defined pack voltage, output current, and/or capacity. Moreover, the implementations discussed herein may apply to different types of electrochemical devices such as various different types of lithium batteries including but not limited to lithium-metal and lithium-ion batteries, lead-acid batteries, various types of nickel batteries, and solid-state batteries of various possible chemistries, to name a few. The various implementations discussed herein may also apply to different structural battery arrangements such as button or “coin” type batteries, cylindrical battery cells, pouch battery cells, and prismatic battery cells. Additionally, the use of the terms “charging recipe” and “charging profile” may include charging signals, discharging signals, and/or cold weather mitigation (e.g., heating) signals.

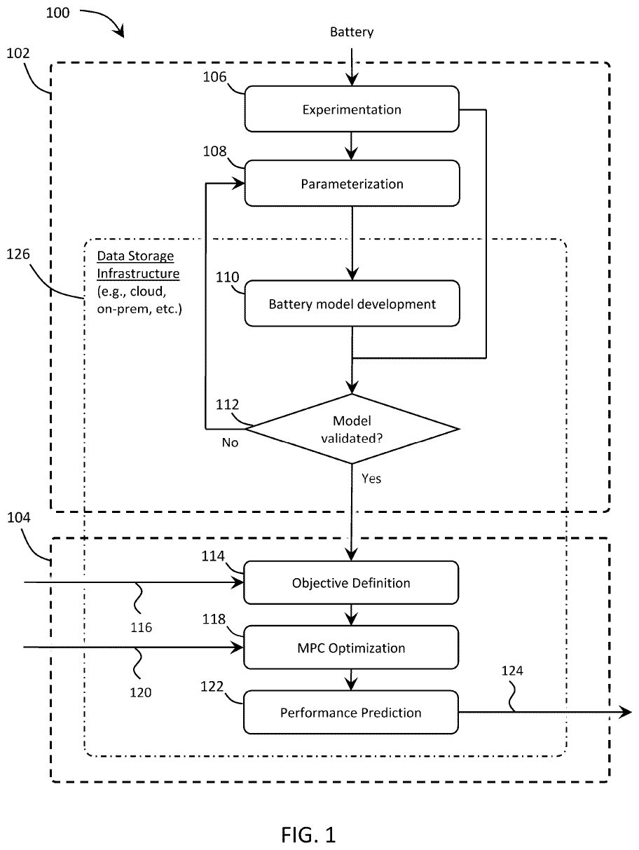

FIG. 1 includes a block diagram showing an overview of a charging protocol development workflow 100 that may be performed using a cycler and system described herein. Specific information about hardware and systems will be provided in further detail below. The workflow 100 may be divided into a discovery phase 102 and a development phase 104. The discovery phase 102 of the workflow includes experimentation step 106 wherein experiments are performed on a battery. The battery may be an unknown battery cell or pack or may be a battery about which some information is known. The experimentation step 106 may include loading the battery into a cycler and obtaining battery feedback data that is generated in response to one or more signals (e.g., probing signals, charging signals, heating signals, etc.) applied to the battery. The step of loading the battery into the cycler may be performed by a user or a technician; the testing processes may be initiated by a user or technician on-site or via remote access to the cycler as will be discussed in further detail below. In general, the cycler may provide charging, discharging or heating signals to a BUT, and the signals may be in all sorts of forms including a simple direct current signal, shaped pulses, signals with sinusoidal overlays, and previously generated recipes.

In some embodiments, the experimentation step 106 includes performing electrochemical impedance spectroscopy (EIS) and/or incremental capacity analysis (ICA) processes to collect EIS/ICA data on a BUT at the cycler. In some embodiments, the battery cycling hardware may include equipment for measuring thickness of a battery cell during charging, discharging, heating, and/or probing. The data obtained from the experimental cycling (e.g., feedback signals, measurements, and information about the battery from experimentation step 106) may be provided to a parameterization step 108 and to a cell model validation step 112 where it will be used as a baseline against which simulated data is compared.

The parameterization step 108 is performed to obtain information about physical, geometric, and/or performance-based battery parameters. The purpose of parameterization is to determine (e.g., measure, calculate, estimate, fit to data, simulate, model, extrapolate from prior or third-party test data, and/or receive from a battery manufacturer) critical electrochemical parameters. In some embodiments, the parameterization step includes battery tear-down in a controlled environment, material measurement, material characterization and/or further experimentation, cycling, or testing of a battery. In some embodiments, a library of battery data may include parameterization information if the specific battery has previously undergone this intensive study. In such cases, the parameterization data may be accessed from a data library stored in a database.

The parameterization step 108 may further include obtaining battery information, characteristics, or parameters using a model (e.g., a physics-based, statistical and/or a machine learning model). Thus, the battery information may be obtained from model simulations, calculations, or other computational and/or data-based analysis. In some embodiments, this portion of the parameterization step may be performed on a data storage infrastructure 126 (e.g., on a cloud-based or on-premises data storage infrastructure). The parameterization data may be used during battery model development step 110.

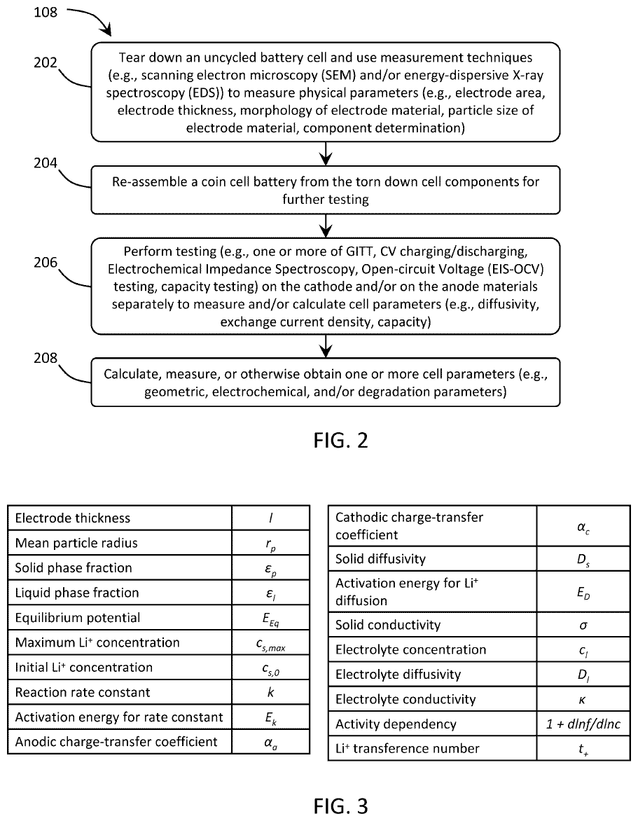

Referring briefly to FIG. 2, additional detail about parameterization is provided. In Step 202 of the parameterization process 108, a new (e.g., uncycled) battery may undergo a tear-down process where the battery is disassembled into individual components. Measurements (e.g., using scanning electron microscopy (SEM) and/or energy-dispersive X-ray spectroscopy (EDS)) may be made on one or more of the battery components to measure physical parameters. Measured physical parameters may include one or more of electrode area, electrode thickness, morphology of electrode material, particle size of electrode material, component determination, or other parameters. The parameterization process continues at Step 204 where components of the torn down battery are assembled to create a battery from the parameterized components that may be further processed. In one specific example, the battery being parameterized may be a cylindrical cell, pouch cell, coin cell or other cell type but regardless of initial cell type prior to tear down, a coin cell is fabricated from the parameterized and initial battery components. In some instances, a battery may be received that has been parameterized and reassembled in coin cell form.

Further testing is performed on the assembled battery at Step 206. In some embodiments, the further testing may include one or more of Galvanostatic Intermittent Titration Technique (GITT), constant voltage (CV) charging and/or discharging, Electrochemical Impedance Spectroscopy (EIS), Open-Circuit Voltage (EIS-OCV), and capacity testing. Testing may be performed on the cathode and/or on the anode materials separately to measure or calculate additional cell parameters such as diffusivity, exchange current density, and capacity. Calculating, measuring, or otherwise obtaining one or more cell parameters based on the testing of step 206 may be completed at step 208. The cell parameters may include geometric, electrochemical, and/or cell degradation parameters.

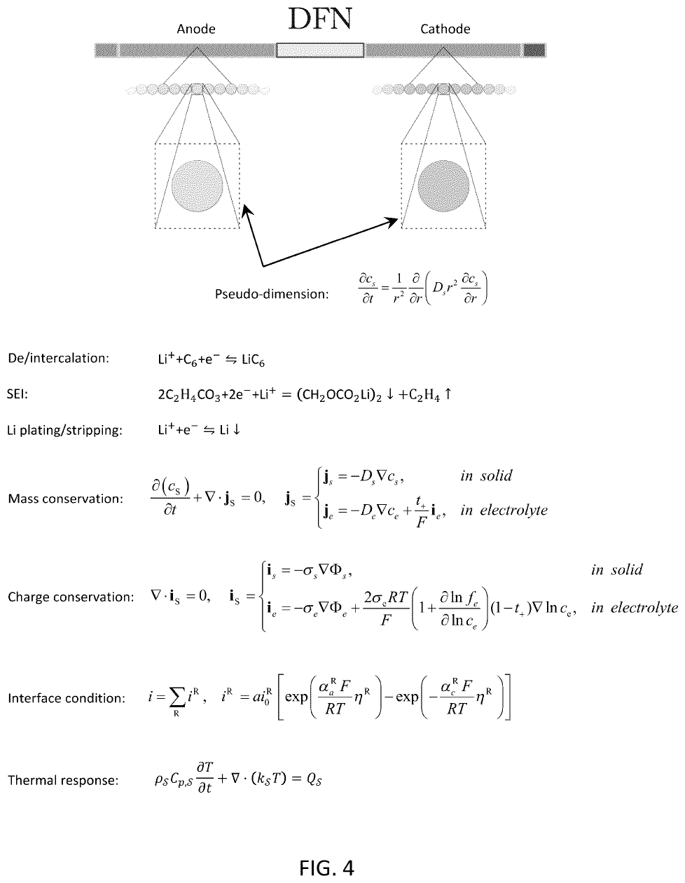

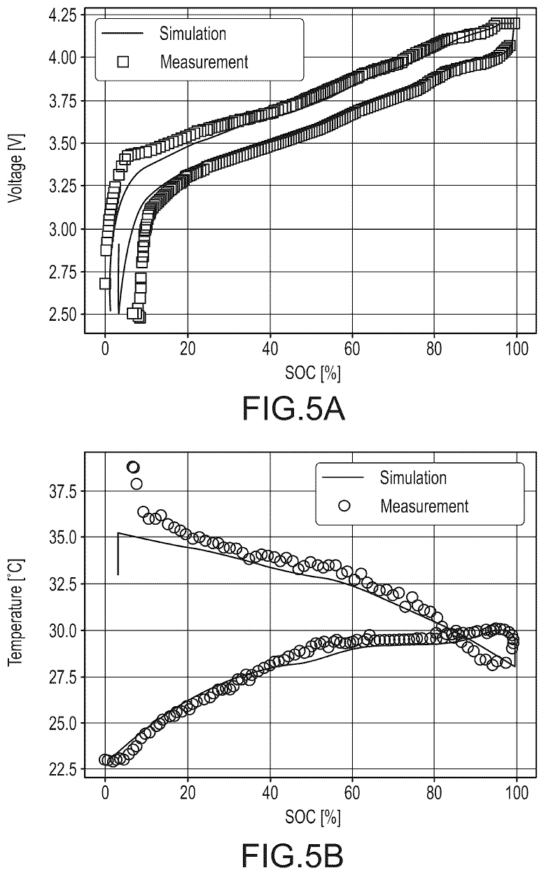

Referring back to FIG. 1, battery-specific parameters determined through the parameterization process 108 are provided to a battery model development step 110. A list of variables that may be used to generate the battery model is included in FIG. 3; more, fewer, or different variables may also be used depending on the particular battery and available information from the parameterization step and/or other sources. Battery model development may include building a physics-based model of the battery. FIG. 4 includes a list of equations that may be used during generation of the battery model. For example, equations describing pseudo-dimension, deintercalation/intercalation, solid electrolyte interface (SEI), lithium plating or stripping, mass conservation, charge conservation, interface condition, and thermal response may be used.

Battery model 110 may include one or more of a machine learning model, an equivalent circuit model, and/or a physics-based model. In some embodiments, a physics-based modeling system, such as a Python-based mathematical modeling software tool may be used. The battery model 110 may include a combination of a machine learning model with an equivalent circuit model and/or a physics-based model to improve model accuracy and/or to reduce time or data required to build the model 110. Once the battery model is developed, it may be used to perform a variety of simulations. For example, the model may be used to simulate electrochemical, thermal, and aging effects under different charging, discharging, and environmental conditions. Battery model simulations may be run that correspond to the testing conditions and experiments performed during experimentation step 106. In some embodiments, the battery model 110 is used to simulate temperatures, State of Health (SOH) and/or other charge metrics (e.g., anode overpotential, SEI thickness, capacity loss, and other battery parameters).

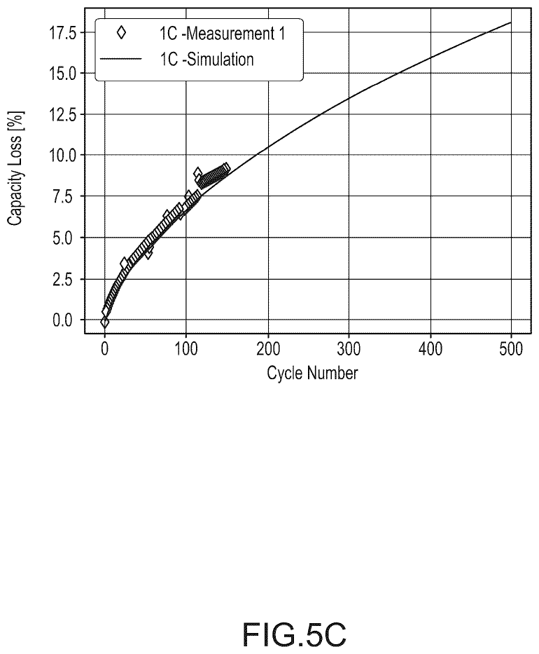

Referring back to FIG. 1, data from the battery model simulation may be compared to the data from experimental battery cycling at a model validation step 112. Examples of comparisons between measurement data (e.g., experimental data) and simulation data are shown in the Voltage vs. SOC graph, Temperature vs. SOC graph, and Capacity Loss vs. Cycle Number graphs of FIGS. 5A, 5B, and 5C, respectively. If the experimental and simulated data sets are sufficiently similar (e.g., within pre-determined thresholds or error tolerance) for certain measured variables (e.g., voltage, temperature, and/or capacity loss), the battery model is determined to be valid, thereby passing the model validation step 112. The workflow 100 then continues to the development phase 104. However, if the battery model does not sufficiently match the experimental cycling data at the model validation step 112, additional testing and parameter measurement may be carried out by repeating the parameterization step 108, or portions thereof. The additional or refined parameters are again provided to the battery model development step 110 where the battery model may be refined or redeveloped based on the new information. This iterative cycle may continue until the battery model is successfully validated at battery validation step 112.

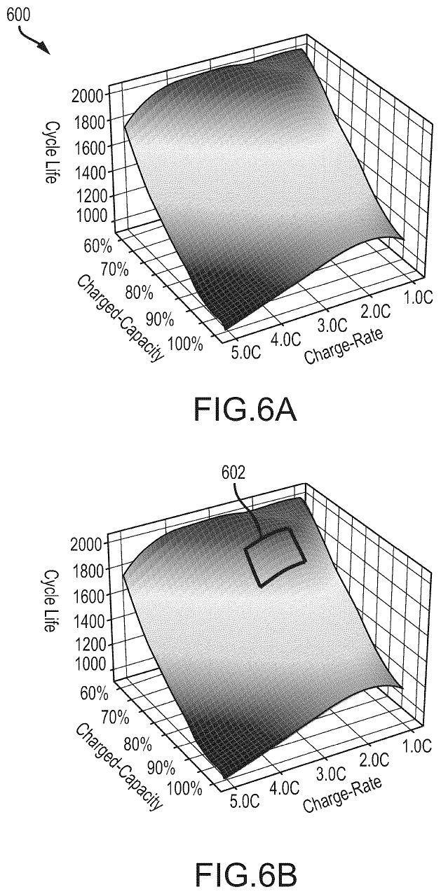

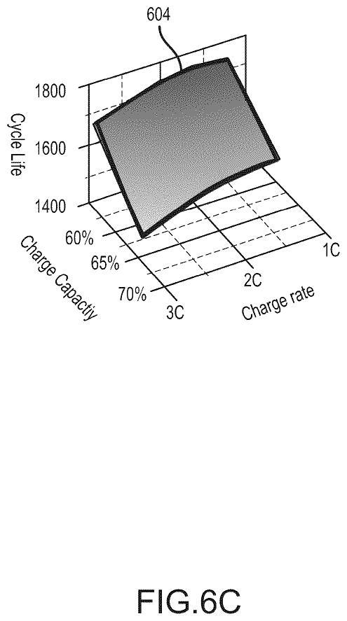

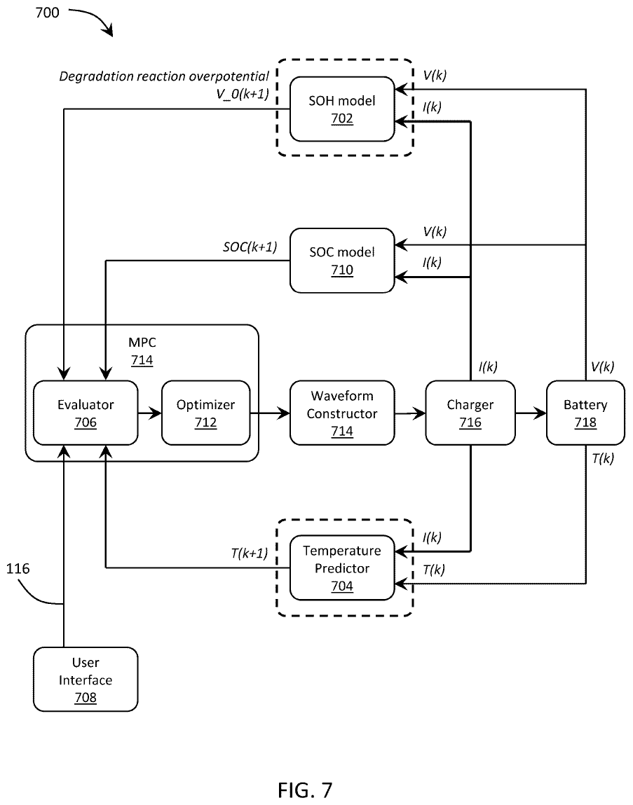

After a battery model has been validated, a battery performance report may be generated. The performance report may demonstrate the battery's capabilities, performance characteristics, and relationships between different input variables. For example, FIG. 6A shows a three-dimensional performance graph 600 that illustrates a battery's performance in terms of the relationships between different variables such as charge rate, charged capacity, and cycle life. To save time and data processing resources, the performance graph 600 may represent a rough mesh version of the battery's performance capabilities over a large range. This rough performance report may be provided as an output following battery model validation and may be used by an engineer, technician, or other user to understand the battery's capabilities and to define targets for a final battery charging profile.

Referring to FIGS. 1, 6B, and 6C together, a performance preference input 116 is provided by a user as part of an objective definition step 114. The performance preference input may be used to select an area of interest 602 (e.g., a smaller range of variables on the performance graph as illustrated in FIG. 6B) that represents charging capabilities and battery performance of most interest to the user. In some embodiments, the performance preference may include selection of a set of variable constraints (e.g., cycle life, charge capacity, charge rate and/or other performance targets). In some embodiments, the performance graph 600 may be interactive with drop down menus, fields in which desired values or ranges may be entered, or directly selectable areas. The area of interest 602 on the performance graph may represent a portion of the performance graph that a user identifies as being suitable or desirable for a particular application. Once the new limits are established by the selection of an area of interest via performance preference 116, a more granular set of simulations may be completed to further refine battery performance information within the area of interest 602. Once the additional simulations are completed, an updated performance graph 604 as shown in FIG. 6C may be generated and provided to the user. The updated performance graph 604 may show more detailed relationships between variables based on the additional simulations.

The workflow 100 may then move forward to a Model Predictive Controller (MPC) optimization step 118. Using battery performance information generated in prior steps, such as the performance graph 600 and/or the updated performance graph 604, a user may provide additional input 120 to the MPC optimization step 118. The additional input 120 may be one or more specific points from the performance graph 600 and/or updated performance graph 604, each of which is associated with a specific charging profile that must be developed in order to achieve the selected performance outputs. Thus, the user provides a selection of at least one charging profile of interest. In some embodiments, two or more charging profiles may be selected and MPC optimization processes may be completed for each. This may be the case when a user wants multiple viable charging profiles or when a user wants to compare final results of more than one charging profile.

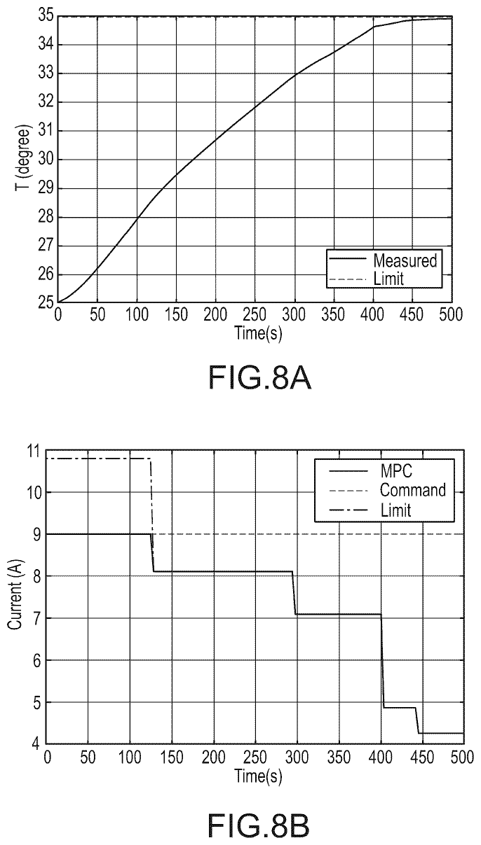

During the MPC optimization step, a controller is trained and optimized for each of the selected charging profiles. The MPC optimization step may take into account additional constraints, such as device hardware limitations, maximum voltages, maximum temperatures, or other user-provided inputs. Training the MPC may be performed using a system as shown in FIG. 7. An example block diagram 700 illustrates various modules and hardware that may be involved in training and validating an MPC. Battery models (e.g., a physics-based battery model, in some embodiments) generated in the discovery phase 102 may be loaded into, or may be otherwise used to inform operation of, a State of Health (SOH) module 702 and/or a temperature predictor module 704 as indicated by dashed line boxes. The user may select one or more charging modules or profiles (e.g., based on the updated performance graph 604) which may be loaded as input 116 into an evaluator module 706 from a user interface module 708. The evaluator module may further receive inputs from the SOH model 702 (e.g., degradation reaction overpotential prediction V_0(k+1) based on current time step voltage V(k) and current time step current I(k)), the State of Charge (SOC) model module 710 (e.g., an SOC prediction for next time step, SOC(k+1) based on V(k) and I(k)), and the temperature predictor module 704 (e.g., temperature prediction for next time step, T(k+1) based on I(k) and current time step temperature T(k)). Current time step voltage V(k) and temperature T(k) may be based on feedback or measurements at a battery 718 loaded into the cycler system. Current time step current I(k) may be provided by a charger 716.

The evaluator module 706 may provide information to an optimizer module 712. The evaluator module 706 and optimizer module 712 may form an MPC module 714. The MPC module may generate a charging recipe for the battery 718 given the future time step prediction information and inputs from the user. In some embodiments, the trained MPC may be tested, verified, or further optimized using a battery 718. In such scenarios, the MPC module 714 may provide the charging recipe to a waveform constructor 714 which in turn operates the charger 716. The charger 716 provides the selected charging recipe to the battery 718. Adjustments to the MPC may be made based on feedback information received during one or more charging, discharging, heating, or probing processes. Once the feedback signals are within tolerance of expected values, optimization is complete and the MPC is ready for use.

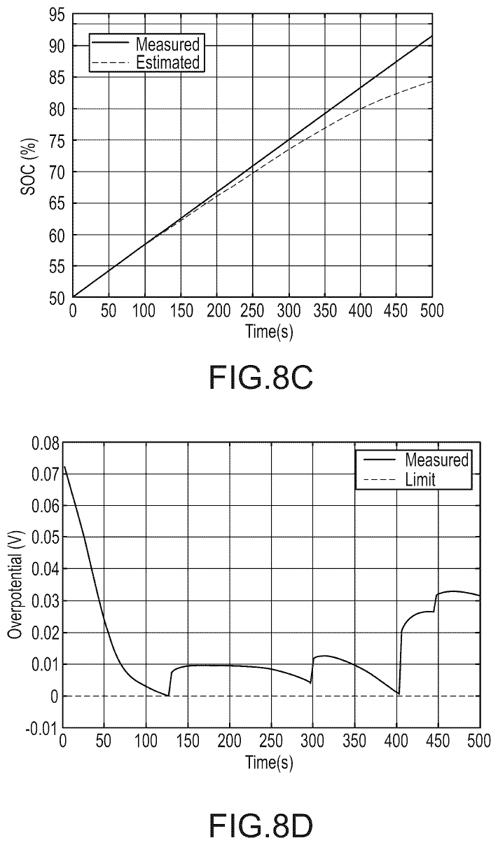

Output from the MPC includes a charging recipe that may take one or more different shapes. For example, the MPC may produce a charging signal with one or more direct current (DC) portions, pulsed portions, shaped leading edge current increase portions (e.g., curved, ramped, sinusoidal, or linear approximations of sinusoids), or other shapes or repeating waveforms based on voltage or SOC parameters. Examples of MPC simulations for battery charging using temperature and SOH models are shown in FIGS. 8A-8D. FIG. 8A shows a maximum temperature limit (e.g., at around 35 deg) and also shows measured (or predicted) temperature as a function of time. With the charging profile used, the battery did not exceed the temperature limit. FIG. 8B shows current as a function of time for a current constraint limit and for the MPC output; the current constraint is not exceeded. FIG. 8C shows SOC as a function of time for a preferred performance reference and for an estimate of a charging profile. While the target is not matched completely, it follows the reference closely during a majority of the time shown. FIG. 8D shows a graph of anode overpotential over time with measured data staying above a lower limit (e.g., OV).

Referring back to FIG. 1, in some embodiments, a performance prediction step 122 may follow the MPC optimization step 118. To complete the performance prediction step, a new battery may be loaded into the battery cycler. The MPC optimized for the selected charging profile runs the charging, discharging, heating, and/or probing cycles to confirm that measured battery responses align with simulated responses. This performance prediction step may provide an additional confirmation that the charging profile delivered by the trained MPC generates the expected battery performance for the given battery cell. A report may be generated and provided to a user, recipe developer, engineer, and/or customer, along with the optimized MPC, as output 124.

In some embodiments, code associated with the charging profile and/or the optimized controller (e.g., the optimized MPC) may be uploaded to the cloud or other remote or local data storage system. The uploaded code may be encrypted or otherwise secured in order to prevent access by unauthorized parties. The uploaded code may be accessed securely by one or more authorized parties for downloading. In some embodiments, the code may be flashed onto a microchip for use in a battery-powered device or system.

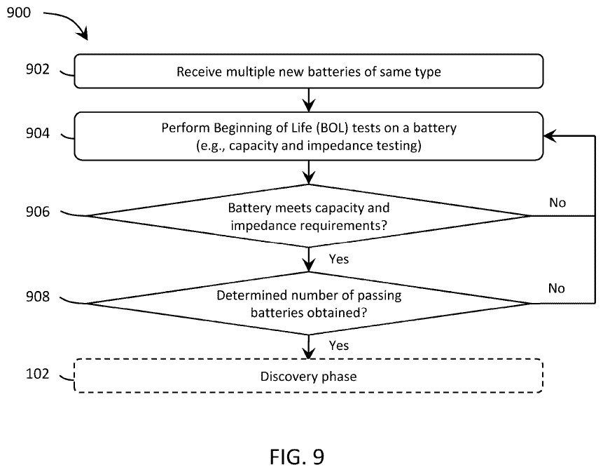

Referring to FIG. 9, a block diagram is shown to describe a method 900 for testing and qualifying battery cells prior to the beginning of workflow 100. A pre-determined number of batteries may be required to complete the workflow 100. For example, this number may be a sum of the number of battery cells that are used during experimentation step 106, parameterization step 108, model validation step 112, MPC optimization step 118, performance prediction step 122, and/or other testing and validation steps for each of the battery charging profiles generated using the workflow 100. The optional battery qualification process 900 may be completed to ensure that each battery used during the workflow 100 is generally representative of the quality and characteristics that would be expected from an average battery of the same type. This process is intended to prevent the use of defective batteries during development of the charging profile.

At step 902, a group of batteries is received for initial testing. The number of batteries received may be greater than the number of batteries required to complete the workflow 100. At step 904, a battery is taken from the group received at step 902 and beginning of life (BOL) tests are performed, such as capacity testing and impedance testing. The results of the BOL tests are compared to expected capacity and impedance measurements at decision block 906; if the tested battery meets or exceeds the expected values, the battery is determined to have sufficient quality to use during the workflow 100. In some embodiments, quality may be assessed using battery capacity and impedance measurements compared to expected values. If the tested battery does not meet expected values, it is not used during workflow 100 and another battery from the batteries received at step 902 is tested. At decision block 908, a determination is made about whether the number of passing batteries is equal to the number of batteries required to complete the workflow 100. If the result of decision block 908 is yes, the passing batteries are made available for using during the workflow 100, beginning with discovery phase 102. If the determination at decision block 908 is no, additional battery testing is performed using steps 904, 906, and 908.

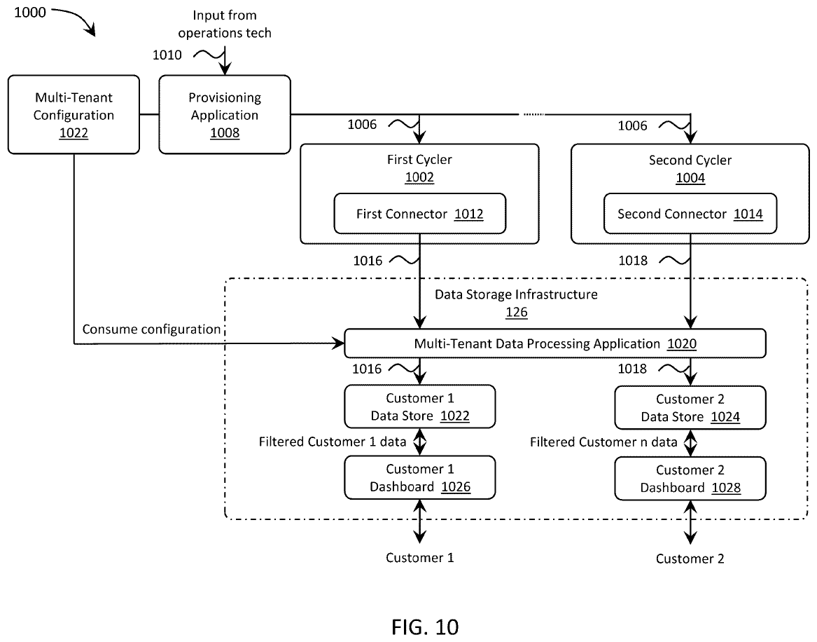

Referring now to FIGS. 1 and 10 together, at least a portion of the workflow 100 occurs on data storage infrastructure 126, represented by the dash-dot boxes in FIGS. 1 and 10. The data storage infrastructure may be located on the same premises as the cycling equipment or may be remotely located. In some embodiments, the data storage infrastructure 126 is a cloud-based infrastructure. The data storage infrastructure may be configured to allow secure, remote access of data and/or battery cycler hardware by a user (e.g., a customer and/or an operator).

FIG. 10 shows an example diagram of a system 1000 that includes a data storage infrastructure 126 and a plurality of battery cyclers. Specifically, the system 1000 includes a first cycler 1002 and a second cycler 1004. Two cyclers are illustrated in order to convey the multi-cycler system concept, but more than two cyclers may be included in the system without departing from the scope of the present disclosure. The system 1000 includes a provisioning application module 1008 configured to receive input 1010 from an operations technician (e.g., through a user interface that may be on-site or remote, not shown). The provisioning application module 1008 may generate an output 1006 based on the input 1010, where the output 1006 is pushed to one or more of the plurality of cyclers 1002, 1004.

In the system 1000, the first cycler 1002 is configured to support cycling operations for a first customer (e.g., Customer 1) and a second cycler 1004 is configured to support cycling operations for as second customer (e.g., Customer 2). Other embodiments are possible where a plurality of cyclers is assigned to a single customer, different cyclers support different projects for the same customer, or where additional customers and cyclers are supported. First and second cyclers 1002, 1004 include a first connector 1012 and a second connector 1014, respectively, configured to transfer data between the cycler and the data storage infrastructure 126. As discussed with respect to FIG. 1, data storage infrastructure 126 may be cloud-based, located at a customer facility, located at a cycler operator's facility, located on the same premises as the cyclers, or otherwise remotely or locally housed.

The output data 1016, 1018 from first and second cyclers, respectively, may be provided by software-based first and second connectors to a multi-tenant data processing application 1020 on the data storage infrastructure. The output data 1016 may be data associated with the cycling operations performed by or for a first customer, while the output data 1018 may be data associated with the cycling operations performed by or for a second customer. The multi-tenant data processing application 1020 consumes a configuration provided by the multi-tenant configuration module 1022. This module may receive provisioning information from the provisioning application 1008 as shown. The multi-tenant data processing application 1020 may ensure that data from different cyclers and/or data associated with different customers or projects is kept separated in customer- and/or project-based data stores. In the system 1000, output data 1016 is stored in Customer 1 data store 1022 and output data 1018 is stored in Customer 2 data store 1024. In some embodiments, there may be a data store associated with each customer and/or a data store associated with each cycler. Organizing data in this way and providing communication between each data store and a dashboard may facilitate secure access of data by an approved group of users (e.g., customers, contractors, engineers, operations technicians, etc.) via a dashboard. In the system 1000, Customer 1 data store 1022 is in communication with Customer 1 dashboard 1026 and Customer 2 data store 1024 is in communication with Customer 2 dashboard 1028. Dashboards 1026, 1028 may receive or request information from data stores 1022, 1024, respectively; however, Customer 1 dashboard cannot communicate with Customer 2 data store, and vice versa. Customer 1 may receive or request information from Customer 1 dashboard 1026 and Customer 2 may receive or request information from Customer 2 dashboard 1028. In some embodiments, communication between customers or users and the data storage infrastructure 126 occurs over a local or remote user interface.

The dashboards 1026, 1028 may include data, summaries, performance metrics, cycler status, cycling process information, timelines, estimated time to task completion, or other raw or summarized data for display to a customer or other approved user. The dashboards may be populated and updated as additional information is available in the data stores. In some embodiments, the dashboards may be interactive or customizable based on a user or operator input. The user interface (UI) that a customer or user interacts may be configured to enable remote control of various charging, discharging, heating, probing and/or testing functions on the cycler. The UI is configured to receive user input (e.g., data, parameters, preferences, selections, etc.) and to output reports that display information related to a specific battery, charging protocol, customer, and/or application. As discussed, the UI and software are designed to compartmentalize data by customer and/or by project such that data reported is specific to the customer. Further filtering and/or sub-compartmentalizing of data may also be performed (e.g., automatically and/or at the request of the user or customer via the UI) to access reports on specific data or projects. In some embodiments, the UI is a web-based interface. Various security measures may be implemented to ensure that dashboards are accessed by approved customers/users only (e.g., password-protected logins, pin numbers, biometrics, two-factor authentication, etc.).

In some embodiments, the dashboards may include a user interface configured to receive inputs from the customer or user. These inputs may be provided to the cycler that is associated with the customer and/or project. For example, Customer 1 may provide instructions to the first cycler 1002 to start, stop, adjust, modify, pause, schedule, or perform other cycler actions. Additionally, as discussed with respect to FIG. 1, a user may be requested to provide input (e.g., input 116, input 118) at various points during a battery charging development workflow 100. The requests may be viewed through the user interface, and the customer or user may be able to complete this requested action through the user interface. This functionality may advantageously support a customer running, overseeing, guiding, or approving cycling operations remotely so that the customer does not need to purchase, store, and supervise expensive on-site battery cycling equipment.

One or more of the battery cyclers (e.g., cyclers 1002, 1004) may include circuitry capable of delivering a shaped charging waveform and/or a cold weather mitigation waveform (e.g., a heating waveform) to a battery cell or pack connected thereto. Examples of such circuitry are discussed in further detail below. In addition to generating accurate and complex sinusoidal, linear piece-wise approximations of sinusoids, ramps, or other charging signal shapes, the cycler is also capable of producing constant current (CC) and/or constant voltage (CV) charge signals. In some embodiments, the cycler may produce heating waveforms, as will be discussed in more detail below. A charge protocol developed for a specific battery cell or pack may include one or more of these different charging signals and/or heating signal types. A transition between different types of signals may be triggered based on one or more detected, measured, or calculated parameters and the result of a comparison of one or more parameters to pre-determined thresholds.

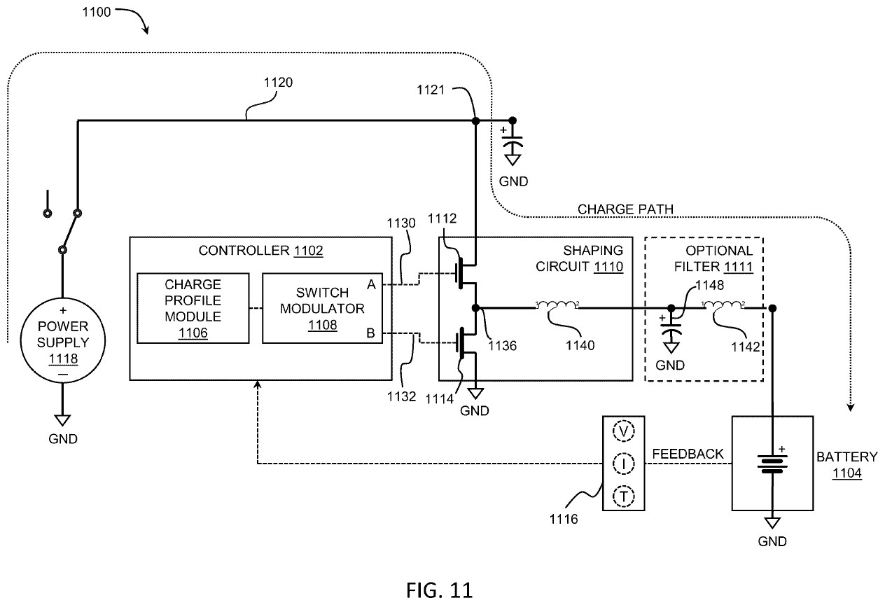

A variety of charging circuit topologies may be used to produce signals having the different shapes described above. FIG. 11 shows a block diagram of one such example circuit 1100. The circuit 1100 includes a charge path for charging a battery 1104. Power source 1118 may generate an input charge supply in the form of an AC or DC input charge supply. In embodiments where power source 1118 generates an AC signal, an AC/DC converter may be included ahead of node 1121 to convert the input charge supply to a DC signal. The circuit 1100 includes a controller 1102 in communication with a shaping circuit 1110. The controller 1102 may include a charge profile module 1106 (e.g., a module configured to provide charging profile instructions) in communication with a switch modulator 1108. The module 1106 and/or other components within a broader cycler system may receive feedback information about the battery through one or more sensors 1116. The feedback information may include sensor measurements (e.g., temperature, voltage, current, etc.) and/or calculated or derived information (e.g., SOC, SOH, impedance, etc.). The switch modulator 1108 may include, or may itself be, a pulse width modulator (PWM).

In the system 1100, a shaping circuit 1110 includes a first switching element 1112 and a second switching element 1114. The switching elements may be electrically controlled switching elements such as transistors, field effect transistors (FET), or more particularly metal-oxide-semiconductor field-effect transistors (MOSFET), Gallium Nitride (GaN) FETs, Silicon Carbide based FETs, or any other type of wired or wireless controllable switching element suitable for operating at the power levels of any given use case or implementation. The first and second switching elements 1112, 1114 each include a source, a gate, and a drain. The source of the first switching element 1112 is electrically coupled with the bus 1120 (e.g., at node 1121) and is configured to receive an input charge supply from power supply 1118. The gate of the first switching element 1112 is configured to receive a first instruction signal 1130 from switch modulator 1108 within controller 1102. The drain of first switching element 1112 is electrically coupled with a source of the second switching element 1114 (e.g., at a node 1136) such that the first and second switching elements are arranged in series. The gate of the second switching element 1114 is configured to receive a second instruction signal 1132 from the switch modulator 1108, and a drain of the second switching element is connected to ground.

Shaping circuit 1110 further includes a first inductor 1140. A filter 1111 may be included following the shaping circuit 1110. The filter 1111 may include a capacitor 1148 and a second inductor 1142. The first inductor 1140 in addition to components within the filter may be configured to shape the cyclical charge supply generated at node 1136 by the controlled switching of switching elements 1112, 1114. The inductors 1140, 1142 and capacitor 1148 are configured to modify input charge supply received from node 1136 such that a shaped charge signal, or a charge signal having a desired current that may change over time as dictated by the charge profile module 1106, is generated for delivery to the battery 1104. Other circuit layouts wherein a power supply is combined with various switching elements, inductors, capacitors arranged in parallel and/or series may be used without departing from the scope of the present disclosure.

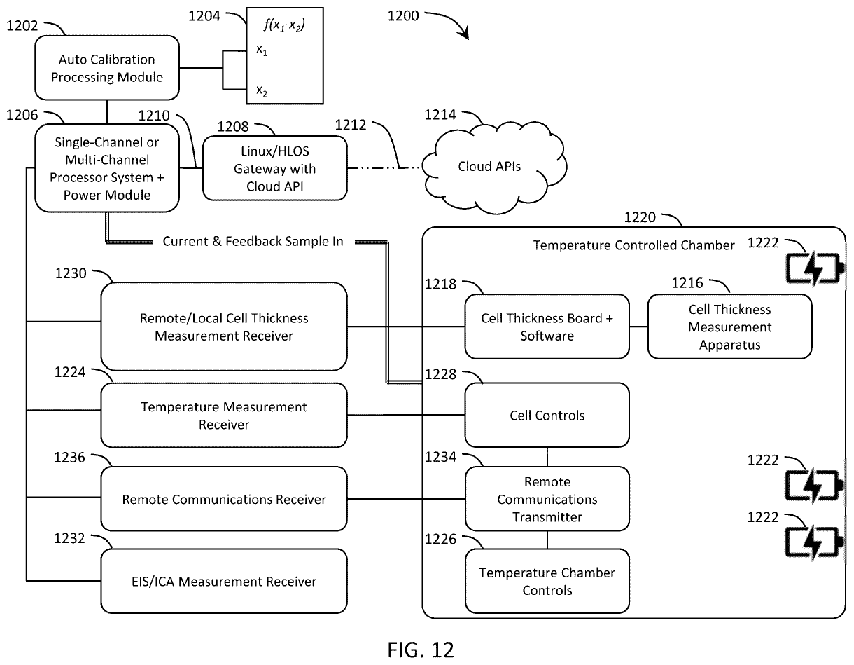

FIG. 12 shows a block diagram for a system 1200 that performs automated and calibrated measurements of battery cells and/or packs. In some embodiments, the system 1200 is configured to perform electrochemical impedance spectroscopy (EIS), incremental capacity analysis (ICA), cell thickness, and contact impedance measurements. The system 1200 may also support other electrical and/or physical properties measured in situ or using remote instruments with electrical communication controlled through a software-controlled master. The system 1200 is further configured to perform cell or pack cycling (e.g., charging and/or discharging). The system 1200 may be implemented on a battery cycler, such as the cyclers 1002, 1004 discussed with respect to FIG. 10.

The system 1200 includes an auto-calibration processing module 1202 configured to determine a difference between an actual measurement value and an expected measurement value for calibration purposes (e.g., using input from module 1204). The calibration information is provided to a single- or multi-channel processor system and power module 1206. The module 1206 may be software controlled through a Linux/HLOS based gateway 1208 running a software module that communicates over a secure channel 1210 to the MCU/Processor board module 1206 and over an ethernet communication channel 1212 with a Cloud Based Framework 1214 (e.g., Amazon Web Services, etc.). All security functions may be natively controlled by the processor and software on the main board 1206. A battery charge recipe for any protocol that includes a constant current/constant voltage (CC/CV), multi-step, dynamic, static, waveform-based protocol and/or other types of charge protocols may be sent remotely to the system 1200 through software interfaces on the cloud application programming interfaces (API) 1214 or through the Linux gateway 1208.

A cycler supporting the system 1200 may be set up in a calibration mode remotely or locally. The cycler may be calibrated using specialized calibration equipment, and the processor and software board 1206 may be configured to provide a known current and/or voltage thereto. Calibration tables, slopes, and/or offsets may be locally stored with timestamps on an Electrically Erasable Programmable Read-Only Memory (EEPROM) of the cycler or may be sent to cloud storage where it may be tagged with a Universally Unique Identifier (UUID) for the associated cycler, a die identification of the main processor, a media access control (MAC) address of the ethernet adapter, and/or the internet protocol (IP) address on the network where the cycler has been installed.

The software system may be configured to perform a calibration verification at any test points desired through software controls. In some embodiments, calibration verification may be triggered by an input from a cycler operator, may be triggered by the occurrence of a predetermined set of events, and/or may be performed at regular intervals. In some embodiments, the software system allows for automated triggers from drift or-recalibration reminders to ensure seamless operation. The system may automatically calibrate and measure changes in measurements, for example, battery impedance measurements, that may occur due to the addition of impedance via cables, temperature change, or other loads. The automatic calibration may include running an impulse response test triggered by the software controls.

The system 1200 also supports an onboard EIS/ICA measurement system through a set of high accuracy (e.g., <0.5% error) circuits and a software system that is software-controlled. EIS is a method of safely characterizing the impedance of the Li-ion cell over a range of frequencies. This allows for determination of the State of Health (SOH) and State of Charge (SOC) of the battery. In some embodiments, a potentiostatic method may be used (e.g., by exciting the battery with voltage to measure impedance values). ICA may be used for measuring the State of Heath (SOH) of the cells. ICA testing may a require significant amount of time and may be performed periodically over the course of the battery's life. Integrating EIS and/or ICA circuitry within a cycler enables new methods of operating a cycler where the cell does not need to be manually removed from the cycler, loaded into a separate EIS/ICA testing equipment, and then manually replaced back into the cycler. This improvement may allow for more frequent EIS/ICA measurements to be obtained and may also have the advantage of facilitating collection of EIS/ICA data simultaneously, or nearly simultaneously, with other battery feedback data (e.g., temperature, electrode voltage, electrode current, etc.).

The software system may be triggered locally or through a cloud API. The system 1200 may be programmed to perform automated measurements without the need for manual intervention by setting up the protocol steps in the configuration (e.g., via provisioning application 1008 as discussed with respect to FIG. 10) before the start of cycling processes. Alternatively or additionally, manual changes may be made to the EIS/ICA measurement process or timing as desired during cycling processes via remote or local software controls. In some embodiments, EIS and/or ICA measurement equipment (not shown) may be included in the system 1200 and may be configured to provide measurement information to an EIS/ICA measurement receiver 1232. The measurements may then by provided to the processor system 1206 for local and/or remote (e.g., cloud-based) storage. The data may be saved with identifier and/or time-stamping information for later analysis.

In addition to the EIS/ICA measurements, the system 1200 may include a cell thickness measurement apparatus 1216 configured to measure battery cell thickness. This equipment may capture changes in thickness of the battery (e.g., a pouch cell) during charging/discharging, such as thickness increases (e.g., swell) or decreases. Thickness measurements may be triggered or otherwise electronically controlled remotely via a cell thickness board and software 1218. The cell thickness measurement apparatus 1216 and the cell thickness board and software 1218 may be located within a temperature-controlled chamber 1220. One or more batteries 1222 may be located within the temperature-controlled chamber and may be measured the cell thickness measurement apparatus 1216 under charging, discharging, and/or rest conditions. The batteries 1222 may be placed in a remote or local setup and once activated through software controls, the cell thickness board and software module 1218, along with the cell thickness measurement apparatus 1216, may perform an accurate cell thickness measurement. Cell thickness measurement data is communicated to the main cycler processor board 1206 via a remote/local cell thickness measurement receiver 1230. The data may be locally saved and/or sent to the cloud. Cloud data may be used develop an automated process (e.g., measurement trigger events, timing, frequency, etc.) for measuring thickness during the battery charge and/or discharge processes. In some embodiments, a communications device is included between the processor system 1206 and the remote cell thickness apparatus 1216 to enable secure and reliable communication over long distances.

In addition to performing thickness measurements, the system 1200 may also perform temperature measurements locally or remotely. The temperature measurements may be performed using temperature measurement equipment (e.g., which may be included in the cell control module 1228) configured to obtain temperature information from one or more batteries 1222 (e.g., cells or packs). The temperature measurement may be received by a temperature measurement receiver 1224 and may be provided to the processor system 1206 where it is saved by the software system in local memory storage and/or in cloud storage. One or more of the temperature measurements may be associated with a particular cycler and/or cycling process (e.g., an experiment) using a timestamp and/or instance tagging. In some embodiments, temperature measurements and/or other battery measurements collected by the cell control module 1228 may be provided to a remote communications transmitter 1234. From the transmitter 1234, the measurement data may be provided to a remote communication receiver 1236 and/or to the temperature chamber control module 1226.

Temperature measurements may be used to control a temperature chamber and/or may be used to control other equipment through a temperature chamber control module 1226. Temperature measurements may be used to initiate or maintain temperature protocols through software APIs (e.g., RESTApis) from the gateway 1208 or the cloud API 1214. In an example, to perform a 0° C. test, software protocol, either through cloud APIs or the gateway 1208, may be automated to inform the cycler to reach 0° C. temperature, may turn off the temperature chamber 1220 without manual intervention, and/or may control the temperature chamber to operate in modes such as continuous cooling, time-based cooling, or other modes to satisfy temperature requirements associated with different testing protocols. In general, the system 1200 (e.g., the temperature-controlled chamber 1220) may automatically react to temperatures measured at the batteries 1222 if a custom protocol for cooling is desired and/or if the cells/packs must be charged or discharged at certain temperatures or within certain temperature ranges.

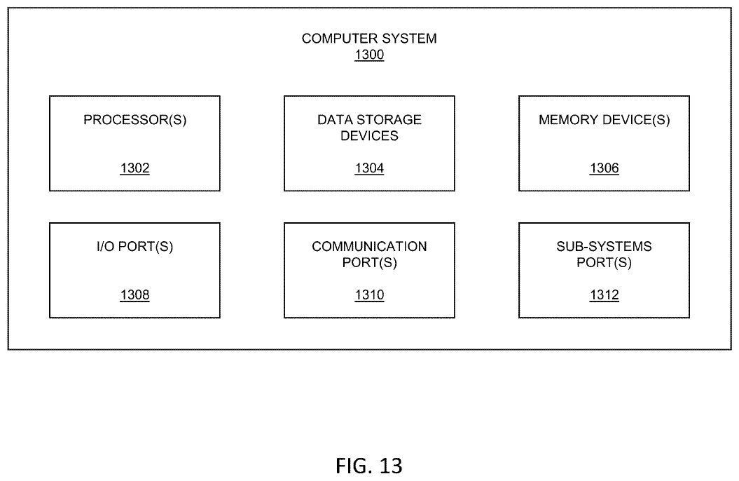

Referring to FIG. 13, a detailed description of an example computing system 1300 having one or more computing units that may implement various systems and methods discussed herein is provided. The computing system 1300 may be part of a controller, may be in operable communication with various implementation discussed herein, may run various operations related to the method discussed herein, may run offline to process various data for characterizing a battery, and may be part of overall systems discussed herein. The computing system 1300 may process various signals discussed herein and/or may provide various signals discussed herein. For example, battery measurement information may be provided to such a computing system 1300. The computing system 1300 may also be applicable to, for example, the controller, the model, the tuning/shaping circuits discussed with respect to the various figures and may be used to implement the various methods described herein. It will be appreciated that specific implementations of these devices may be of differing possible specific computing architectures, not all of which are specifically discussed herein but will be understood by those of ordinary skill in the art. It will further be appreciated that the computer system may be considered and/or include an ASIC, FPGA, microcontroller, or other computing arrangement. In such various possible implementations, more or fewer components discussed below may be included, interconnections and other changes made, as will be understood by those of ordinary skill in the art.

The computer system 1300 may be a computing system that may execute a computer program product to execute a computer process. Data and program files may be input to the computer system 1300, which reads the files and executes the programs therein. Some of the elements of the computer system 1300 are shown in FIGS. 13, including one or more hardware processors 1302, one or more data storage devices 1304, one or more memory devices 1306, and/or one or more ports 1308-1312. Additionally, other elements that will be recognized by those skilled in the art may be included in the computing system 1300 but are not explicitly depicted in FIG. 13 or discussed further herein. Various elements of the computer system 1300 may communicate with one another by way of one or more communication buses, point-to-point communication paths, or other communication means not explicitly depicted in FIG. 13. Similarly, in various implementations, various elements disclosed in the system may or not be included in any given implementation.

The processor 1302 may include, for example, a central processing unit (CPU), a microprocessor, a microcontroller, a digital signal processor (DSP), and/or one or more internal levels of cache. There may be one or more processors 1302, such that the processor 1302 comprises a single central-processing unit, or a plurality of processing units capable of executing instructions and performing operations in parallel with each other, commonly referred to as a parallel processing environment.

The presently described technology in various possible combinations may be implemented, at least in part, in software stored on the data stored device(s) 1304, stored on the memory device(s) 1306, and/or communicated via one or more of the ports 1308-1312, thereby transforming the computer system 1300 in FIG. 13 to a special purpose machine for implementing the operations described herein.

The one or more data storage devices 1304 may include any non-volatile data storage device capable of storing data generated or employed within the computing system 1300, such as computer executable instructions for performing a computer process, which may include instructions of both application programs and an operating system (OS) that manages the various components of the computing system 1300. The data storage devices 1304 may include, without limitation, magnetic disk drives, optical disk drives, solid state drives (SSDs), flash drives, and the like. The data storage devices 1304 may include removable data storage media, non-removable data storage media, and/or external storage devices made available via a wired or wireless network architecture with such computer program products, including one or more database management products, web server products, application server products, and/or other additional software components. Examples of non-removable data storage media include internal magnetic hard disks, SSDs, and the like. The one or more memory devices 1306 may include volatile memory (e.g., dynamic random-access memory (DRAM), static random-access memory (SRAM), etc.) and/or non-volatile memory (e.g., read-only memory (ROM), flash memory, etc.).

Computer program products containing mechanisms to effectuate the systems and methods in accordance with the presently described technology may reside in the data storage devices 1304 and/or the memory devices 1306, which may be referred to as machine-readable media. It will be appreciated that machine-readable media may include any tangible non-transitory medium that is capable of storing or encoding instructions to perform any one or more of the operations of the present disclosure for execution by a machine or that is capable of storing or encoding data structures and/or modules utilized by or associated with such instructions. Machine-readable media may include a single medium or multiple media (e.g., a centralized or distributed database, and/or associated caches and servers) that store the one or more executable instructions or data structures.

In some implementations, the computer system 1300 includes one or more ports, such as an input/output (I/O) port 1308, a communication port 1310, and a sub-systems port 1312, for communicating with other computing, network, or vehicle devices. It will be appreciated that the ports 1308-1312 may be combined or separate and that more or fewer ports may be included in the computer system 1300. The I/O port 1308 may be connected to an I/O device, or other device, by which information is input to or output from the computing system 1300. Such I/O devices may include, without limitation, one or more input devices, output devices, and/or environment transducer devices.

In one implementation, the input devices convert a human-generated signal, such as, human voice, physical movement, physical touch or pressure, and/or the like, into electrical signals as input data into the computing system 1300 via the I/O port 1308. In some examples, such inputs may be distinct from the various system and method discussed with regard to the preceding figures. Similarly, the output devices may convert electrical signals received from computing system 1300 via the I/O port 1308 into signals that may be sensed or used by the various methods and system discussed herein. The input device may be an alphanumeric input device, including alphanumeric and other keys for communicating information and/or command selections to the processor 1302 via the I/O port 1308.

The environment transducer devices convert one form of energy or signal into another for input into or output from the computing system 1300 via the I/O port 1308. For example, an electrical signal generated within the computing system 1300 may be converted to another type of signal, and/or vice-versa. In one implementation, the environment transducer devices sense characteristics or aspects of an environment local to or remote from the computing device 1300, such as battery voltage, open circuit battery voltage, charge current, battery temperature, light, sound, temperature, pressure, magnetic field, electric field, chemical properties, and/or the like.

In one implementation, a communication port 1310 may be connected to a network by way of which the computer system 1300 may receive network data useful in executing the methods and systems set out herein as well as transmitting information and network configuration changes determined thereby. For example, charging protocols may be updated, battery measurement or calculation data shared with external system, and the like. The communication port 1310 connects the computer system 1300 to one or more communication interface devices configured to transmit and/or receive information between the computing system 1300 and other devices by way of one or more wired or wireless communication networks or connections. Examples of such networks or connections include, without limitation, Universal Serial Bus (USB), Ethernet, Wi-Fi, Bluetooth®, Near Field Communication (NFC), Long-Term Evolution (LTE), and so on. One or more such communication interface devices may be utilized via the communication port 1310 to communicate with one or more other machines, either directly over a point-to-point communication path, over a wide area network (WAN) (e.g., the Internet), over a local area network (LAN), over a cellular (e.g., third generation (3G), fourth generation (4G), fifth generation (5G)) network, or over another communication means.

The computer system 1300 may include a sub-systems port 1312 for communicating with one or more systems related to a device being charged according to the methods and system described herein to control an operation of the same and/or exchange information between the computer system 1300 and one or more sub-systems of the device. Examples of such sub-systems of a vehicle, include, without limitation, motor controllers and systems, battery control systems, and others.

The system set forth in FIG. 13 is but one possible example of a computer system that may employ or be configured in accordance with aspects of the present disclosure. It will be appreciated that other non-transitory tangible computer-readable storage media storing computer-executable instructions for implementing the presently disclosed technology on a computing system may be utilized.

Embodiments of the present disclosure include various steps, which are described in this specification. The steps may be performed by hardware components or may be embodied in machine-executable instructions, which may be used to cause a general-purpose or special-purpose processor programmed with the instructions to perform the steps. Alternatively, the steps may be performed by a combination of hardware, software and/or firmware.

Various modifications and additions can be made to the exemplary embodiments discussed without departing from the scope of the present invention. For example, while the embodiments, also referred to as implementations or examples, described above refer to particular features, the scope of this invention also includes embodiments having different combinations of features and embodiments that do not include all of the described features. Accordingly, the scope of the present invention is intended to embrace all such alternatives, modifications, and variations together with all equivalents thereof.

While specific implementations are discussed, it should be understood that this is done for illustration purposes only. A person skilled in the relevant art will recognize that other components and configurations may be used without parting from the spirit and scope of the disclosure. Thus, the following description and drawings are illustrative and are not to be construed as limiting. Numerous specific details are described to provide a thorough understanding of the disclosure. However, in certain instances, well-known or conventional details are not described in order to avoid obscuring the description. References to one or an embodiment in the present disclosure can be references to the same embodiment or any embodiment; and, such references mean at least one of the embodiments.

Reference to “one embodiment” or “an embodiment” means that a particular feature, structure, or characteristic described in connection with the embodiment is included in at least one embodiment of the disclosure. The appearances of the phrase “in one embodiment”, or similarly “in one example” or “in one instance”, in various places in the specification are not necessarily all referring to the same embodiment, nor are separate or alternative embodiments mutually exclusive of other embodiments. Moreover, various features are described which may be exhibited by some embodiments and not by others.

The terms used in this specification generally have their ordinary meanings in the art, within the context of the disclosure, and in the specific context where each term is used. Alternative language and synonyms may be used for any one or more of the terms discussed herein, and no special significance should be placed upon whether or not a term is elaborated or discussed herein. In some cases, synonyms for certain terms are provided. A recital of one or more synonyms does not exclude the use of other synonyms. The use of examples anywhere in this specification including examples of any terms discussed herein is illustrative only and is not intended to further limit the scope and meaning of the disclosure or of any example term. Likewise, the disclosure is not limited to various embodiments given in this specification.

Without intent to limit the scope of the disclosure, examples of instruments, apparatus, methods and their related results according to the embodiments of the present disclosure are given below. Note that titles or subtitles may be used in the examples for convenience of a reader, which in no way should limit the scope of the disclosure. Unless otherwise defined, technical and scientific terms used herein have the meaning as commonly understood by one of ordinary skill in the art to which this disclosure pertains. In the case of conflict, the present document, including definitions will control.

Additional features and advantages of the disclosure will be set forth in the description which follows, and in part will be obvious from the description, or can be learned by practice of the herein disclosed principles. The features and advantages of the disclosure can be realized and obtained by means of the instruments and combinations particularly pointed out in the appended claims. These and other features of the disclosure will become more fully apparent from the following description and appended claims or can be learned by the practice of the principles set forth herein.

What is claimed is:

1. A method of developing a battery charging profile, the method comprising:
performing an experimentation process on a battery, wherein the experimentation comprises generating experimentation data, the experimentation data comprising electrochemical impedance spectroscopy (EIS) data and incremental capacity analysis (ICA) data;
performing a parameterization process on the battery, wherein the parameterization process comprises generating parameterization data, the parameterization data comprising physical characteristics of the battery;
developing a battery model for the battery based on the experimentation data and the parameterization data;
generating simulated battery data using the battery model; and
generating a battery performance report based on the simulated battery data.

2. The method of claim 1, further comprising validating the battery model by determining that the simulated battery data is within a threshold of the experimentation data.

3. The method of claim 1, further comprising:
receiving a first input from a user to identify an area of interest on the battery performance report;
generating refined simulation battery data using the battery model; and
generating an updated battery performance report based on the refined simulation battery data for the area of interest.

4. The method of claim 3, further comprising receiving a second input from a user to select one or more points on the updated battery performance report, each of the one or more points associated with a unique set of battery performance metrics.

5. The method of claim 4, further comprising optimizing a model predictive controller (MPC) for each of the selected points.

6. The method of claim 5, wherein optimizing the MPC comprises generating the battery charging profile based on a future time step prediction of at least one metric.

7. The method of claim 6, wherein optimizing the MPC is further based on at least one performance limitation input from the user.

8. The method of claim 7, wherein optimizing the MPC further comprises:
using the MPC to deliver a charge signal to the battery;
receiving battery feedback for at least one battery performance metric during delivery of the charge signal to the battery; and
validating the MPC by determining that the at least one battery performance metric satisfies the at least one performance limitation input from the user.

9. The method of claim 8, further comprising generating a battery performance prediction based on the battery feedback for the at least one battery performance metric.

10. A multi-channel multi-tenant system for developing a battery charging profile, the system comprising:
a first battery cycler and a second battery cycler, wherein the first and second battery cyclers are configured to deliver a charge signal to a battery disposed therein;
a data storage infrastructure in communication with the first and second cyclers; and
a multi-tenant data processing application stored on the data storage infrastructure,
wherein the multi-tenant data processing application is configured to receive first cycling data from the first battery cycler and second cycling data from the second battery cycler, and
wherein the multi-tenant data processing application is configured to route the first cycling data to a first data store on the data storage infrastructure and is configured to route the second cycling data to a second data store on the data storage infrastructure.

11. The system of claim 10, wherein the data storage infrastructure further comprises a first dashboard in communication with the first data store and a second dashboard in communication with the second data store, and wherein the first dashboard is configured to display information from the first data store and the second dashboard is configured to display information from the second data store.

12. The system of claim 11, wherein the first dashboard and the second dashboard are configured to receive inputs from a user.

13. The system of claim 12, wherein the inputs comprise selection of an area of interest from a battery performance report.

14. The system of claim 12, wherein the inputs comprise selection of a point on an updated battery performance report.

15. The system of claim 12, wherein inputs comprise at least one performance limitation metric.

16. The system of claim 10, wherein one or more of the first cycler and the second cycler is located remotely from the data storage infrastructure.

17. The system of claim 10, wherein the data storage infrastructure is one of a cloud-based infrastructure and an on-premises infrastructure.

18. The system of claim 10, wherein at least one of the first cycler and the second cycler is housed within a temperature-controlled chamber.

19. The system of claim 18, wherein at least one of the first cycler and the second cycler comprises temperature chamber controls configured to control temperature within the temperature-controlled chamber.

20. The system of claim 10, wherein at least one of the first cycler and the second cycler comprises a cell thickness measurement apparatus configured to measure thickness of a battery loaded therein without removing the battery from the cycler.

21. The system of claim 20, further comprising a cell thickness board in communication with the cell thickness measurement apparatus and a cell thickness software configured to run on the cell thickness board and transfer cell thickness measurement data to a cell thickness measurement receiver module.

22. The system of claim 21, wherein the cell thickness measurement receiver is located remotely from at least one of the first and second cycler.

23. The system of claim 21, wherein the cell thickness measurement receiver is located locally compared to at least one of the first and second cycler.

24. The system of claim 10, wherein at least one of the first cycler and the second cycler comprises an EIS measurement apparatus.

25. The system of claim 10, wherein at least one of the first cycler and the second cycler comprises an ICA measurement apparatus.

26. The system of claim 10, further comprising a processor system in communication with at least one of the first cycler and the second cycler.

27. The system of claim 26, wherein the processor system is in communication with an auto-calibration processing module configured to automatically calibrate at least one measurement module on at least one of the first cycler and the second cycler.

28. The system of claim 27, wherein the calibration processing module is configured to calibrate the system for changes in impedance introduced by cables, temperature change.

29. The system of claim 26, wherein the processor is in communication with a gateway configured to receive data from a remote location through a cloud-based API.

30. The system of claim 29, wherein the data received from the remote location comprises a charging signal data.
